(19) United States
(12) Patent Application Publication
(10) Pub. No.: US 2014/0340860 A1
(43) Pub. Date: Nov. 20, 2014

(54) CIRCUIT BOARD AND ELECTRICAL COMPONENTS FOR USE IN AN AGGRESSIVE ENVIRONMENT AND METHOD FOR PRODUCING SUCH A CIRCUIT BOARD

(71) Applicants: Andreas Otto, Hoerselberg-Hainich (DE); Sabrina Rathgeber, Gerlingen (DE); Marc Fischer, Reichenbach (DE)

(72) Inventors: Andreas Otto, Hoerselberg-Hainich (DE); Sabrina Rathgeber, Gerlingen (DE); Marc Fischer, Reichenbach (DE)

(73) Assignee: ROBERT BOSCH GMBH, Stuttgart (DE)

(21) Appl. No.: 14/344,521

(22) PCT Filed: Sep. 6, 2012
(86) PCT No.: PCT/EP2012/067434

§ 371 Date: Mar. 12, 2014

(30) Foreign Application Priority Data
Sep. 12, 2011 (DE) 10 2011 082 537.1

(51) Int. Cl. H05K 3/28; F16H 61/02; H05K 3/30; H05K 1/09; H05K 1/11

(52) U.S. Cl. CPC H05K 3/28; H05K 1/09; H05K 1/111; H05K 3/30; F16H 61/0251
USPC 361/767; 174/257; 361/760; 29/831

(57) ABSTRACT

The invention comprises an at least one-layer electrical circuit board (1) having internal and/or external conducting tracks or electrical circuits (3, 8), which circuit board has copper pads (4, 5) arranged on the surface for population with electrical components and/or which has copper pads (5) for electrically connecting at least two layers of the circuit board, and which is at least partially surrounded by media, in particular liquid media, further in particular oil, or is directly exposed thereto, wherein said copper pads (4, 5) and exposed conducting tracks (8) are coated with a further metal (7).

### BACKGROUND OF THE INVENTION

The present invention relates to a circuit board as well as to electrical components, which are designed in particular as a basis for a control device, for use within aggressive media. It is, e.g., a common practice in the case of automobiles to integrate the control devices for individual components directly into the respective components. For example, a control device for a transmission is directly integrated into the transmission itself. The control device must then however be protected from aggressive media (e.g. ATF, automatic transmission fluid). Constituents of such a medium (e.g. sulfur or sulfur compounds) or the medium itself can react with the copper on the circuit board or on the electrical component, whereby the copper can dissolve. In addition, the ATF can form conductive deposits due to condensation or migration of dissolved copper, whereby undesirable conductive compounds can be produced.

In order to protect the control devices, housings are used which hermetically seal off the electrical components from the aggressive media. Despite said protection from aggressive media, care should thereby be taken to provide sufficient heat dissipation so that the components do not overheat.

The German patent publication DE 199 07 949 A1 discloses a device which adequately seals off a circuit board in order to use the same within a transmission. To this end, a circuit board provided with an electrical circuit and consisting of a ceramic substrate (LTCC) is adhesively bonded to an aluminum plate. A plastic cover comprising a circumferential seal is subsequently mounted on the aluminum plate in a positive-locking manner, e.g. by riveting. The electronic circuit can communicate with the environment thereof by means of conducting tracks which leave the sealed off region by passing between aluminum plate and seal.

The German patent publication DE 10 2007 061 116 A1 displays a similar approach. In this case, a first housing part in the form of a tray is used, in which the electrical components are mounted. A cover is connected to said tray in a materially bonded manner, wherein the connection also simultaneously serves as the seal. The tray provides the possibility to dissipate resulting heat by means of the large base area thereof.

Finally, the German patent publication DE 10 2007 045 261 A1 discloses a control device which has only a cover. A circuit substrate, which is usually produced from LTCC, is provided with a circuit. A cover is subsequently mounted to the circuit substrate which hermetically seals the electrical circuit, possibly with the use of an additional seal. A hold-down device is mounted within the cover, which device on the one hand fixedly seats the components and on the other hand is responsible for the heat dissipation.

### SUMMARY OF THE INVENTION

The inventive circuit board and the inventive components can be used directly within a medium which reacts with copper without the functionality of said board and components being reduced. The invention also provides a method for producing such circuit boards or components; and a transmission which comprises such a circuit board and/or such components.

A base plate is used with the inventive circuit board, on which base plate conducting tracks or electrical circuits are provided. If a plurality of such plates is stacked one on top of the other, a circuit board having a multilayer design is formed. Such a base plate consisting of at least one layer has then two surfaces which can be equipped with components. To this end, copper pads are arranged on the surfaces, on which copper pads corresponding electronic components can be soldered. It is thereby immaterial whether the type of mounting relates to a surface-mounting technology (SMT), the through-hole mounting technology (THT) or to another type of mounting technology. In order to protect the copper from aggressive media, the circuit board according to the invention comprises a coating which is correspondingly resistant thereto. For that reason, it is possible to expose the circuit board directly to media which would otherwise dissolve the copper and/or form electrically conductive deposits thereon and thereby drastically shorten the service life of said circuit board.

The electrical component according to the invention consists of a semiconductor chip which is surrounded by a plastic casing. The chip is thus already protected from the surrounding medium. In order to connect the chip to other components, said chip can be mounted to a base plate. In this case, the chip is directly mounted to the base plate and establishes electrical connections with said base plate. The plastic casing serves as the “cover” which rests on the base plate. The base plate is designed analogously to the base plate of the circuit board, has therefore at least one layer and comprises internal and/or external conducting tracks. Furthermore, copper pads are located on the surface of the base plate which serve to produce an electrical connection to other components. To this end, the ball grid array (BGA) or land grid array (LGA) technologies can be used.

In an alternative variant of the electrical component, the chip can be connected to contacting elements made of copper, wherein the contacting elements are partially enclosed by the plastic casing of the chip. This is, e.g., implemented in the construction method known as quad flat package (QFP). The contacting element can thereby consist of copper or another material which is resistant to media that react with copper. In this way, the amount of exposed copper is reduced.

Both variants of the electrical component, which have been described above, have in common that all of the exposed copper is provided with a coating which is resistant to the surrounding media, preferably liquid media, in particular oils. It is therefore possible to expose the inventive electrical component directly to the media, which would otherwise dissolve the copper and/or form electrically conductive deposits thereon and therefore drastically shorten the service life of the component.

In an advantageous manner, the coating on the inventive circuit board or on the inventive components consists of NiAu, NiPdAu, NiPdAgAu, PdAg, Sn or Ag because these metals or metal alloys additionally have good soldering properties. It is furthermore advantageous that all exposed copper layers are completely metallically coated. Only in this way is it ensured that the aggressive medium can no longer reach the copper layers and thus all of the copper of the circuit board is completely insulated from the environment.

If a contacting element is used as a component which is resistant to media that react with copper, the contacting element is then preferably manufactured from pure Sn, Al or Ni or from alloys containing these basic materials (e.g. FeNi) or from electrically conductive plastic. The plastic can either have self-conducting properties or be provided with corresponding conductive additives.

The base plate of the circuit board or component is preferably provided with a solder resist (solder mask) which covers all of the conducting tracks (coated or uncoated) situated on the surface. In addition, the solder resist can either partially cover the copper pads provided for the mounting of components (SMD, solder resist defined) or not come at all in contact with said copper pads (NSMD, non solder resist defined). A mounting of electrical components depending on the requirements profile favoring the one (SMD) or the other variant (NSMD) is thus facilitated.

In a particularly preferred manner, the circuit boards or components are produced using the following methods, which differ depending whether conducting tracks are present on the surface and in how the solder resist is to be applied (SMD or NSMD): The production of circuit boards or components without external conducting tracks and using the layout variant NSMD, i.e. circuit boards or components in which all connections are established in the inner layers, proceeds as follows: The base plate is initially produced which contains at least one copper layer in the interior thereof. In the event that a component is to be produced, a semiconductor chip is subsequently mounted on the surface and electrically connected to the base plate. In order to protect the chip from external influences, the chip and the surface of the base plate are surrounded by a plastic casing. The mounting of the chip and the application of the casing are eliminated if a circuit board is being produced. A solder resist can subsequently be applied to the surfaces of the base plate, said solder resist being applied according to the NSMD method, wherein contact is not made with the copper pads. Due to the fact that the solder resist is spaced apart from the copper pads, it is easily possible to coat the copper pads as a final step.

If the aforementioned configuration is not desired, the formation of triple points must be prevented during production of the circuit boards or components. A triple point forms if solder resist, copper and coating come in contact with each other. For that reason, the production method has to be modified for the layout variant SMD or if external conducting tracks are present.

Circuit boards or components comprising an SMD layout and/or external conducting tracks are preferably produced according to the following method: The base plate having at least one layer is initially produced. In the event that a component is to be produced, a semiconductor chip is subsequently mounted to the surface and electrically connected to the base plate (e.g. by means of bonding). In order to protect the chip from outside influences, the chip and the surface of the base plate are surrounded by a plastic casing. The mounting of the chip and the application of the casing are eliminated if a circuit board is being produced. All of the steps executed to this point are analogous to the preceding method. All of the exposed copper layers (external conducting tracks and/or copper pads arranged on the surface for population with electrical components) can subsequently be completely or partially provided with a coating. After that, the solder resist is applied which can either be configured as an SMD or NSMD layout variant. Because this step can negatively impact the quality of the coating, a check of the surface is preferably performed as a final step in order to refresh the coating if need be.

Components which do not have a base plate but contain a contacting element are preferably produced according to the following method: A contacting is initially produced which consists, for example, of copper or a copper compound (e.g. CuFe2P) or of a material which is resistant to media that react with copper. A coating is then only subsequently applied to the contacting element if said coating contains copper. The contacting element can now be connected to a semiconductor chip prior to a plastic casing being placed around the chip, said plastic casing partially covering the contacting elements. In a final step, the coating, which may be present, is checked and be refreshed again if need be.

In order to prevent a possible ingress of medium between base plate and plastic casing or between contacting element and plastic casing, it is advantageous to improve the adhesion between the two elements. This can take place either by structuring the base plate or contacting element, e.g. by means of a laser, or by applying, for example, a chemical adhesion promoter prior to applying a plastic casing.

The circuit board described above and/or the component described above can preferably serve to produce a transmission control device therefrom. By means of the inventive metallic coating of the exposed copper pads, said circuit board is resistant to media which react with copper as said media occur within transmissions. As a result, the control device no longer has to be shielded from media which react with copper by means of additional measures, as, e.g., by means of a housing, but can be directly exposed to the same. The circuit board can therefore even operate when it is completely surrounded by the medium.

### BRIEF DESCRIPTION OF THE DRAWINGS

Exemplary embodiments of the invention are described below with reference to the accompanying drawings. In the drawings:

FIG. 1 shows a circuit board which is suited to both a surface-mounting technology and a through-hole-mounting technology and has an inventive coating in a “non solder mask defined” embodiment;

FIG. 2 shows a circuit board which is suited to both a surface-mounting technology and a through-hole-mounting technology and has an inventive coating in a “solder mask defined” embodiment;

FIG. 3 shows a component provided for contacting by means of LGA technology and having an inventive coating in a “non solder mask defined” embodiment;

FIG. 4 shows a component provided for contacting by means of LGA technology and having an inventive coating in a “solder mask defined” embodiment; and

FIG. 5 shows a component that contains a contacting element instead of a base plate.

### DETAILED DESCRIPTION

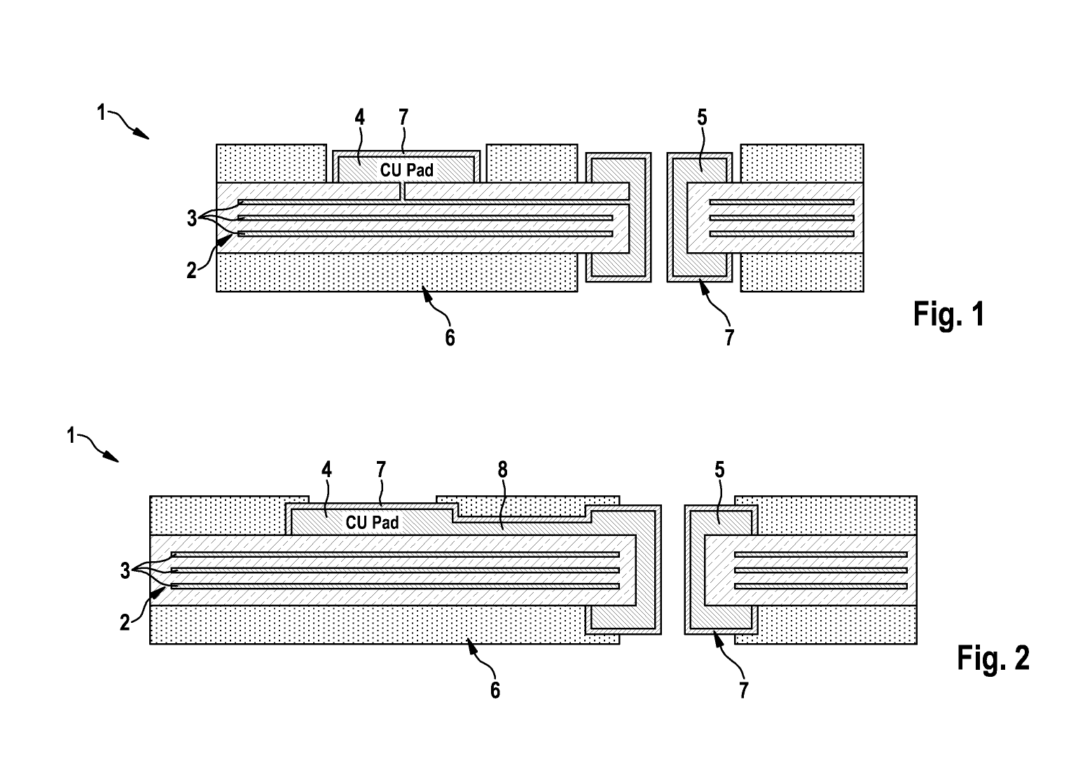

The cross section through a circuit board 1 according to the invention is depicted by means of example in FIG. 1 in a first preferred embodiment. A base plate 2, which is preferably produced from a fiberglass- resin or paper-resin composite material, contains, by means of example, three internal copper layers 3 which contain electrical circuits. Copper pads 4 which can preferably receive components in accordance with SMT technology are located on the surface of the base plate 2. In addition, the base plate 2 contains copper pads 5 which serve as through-plating in order to connect a plurality of internal copper layers and/or provide the contact hole for population with electrical components in accordance with THT technology.

A solder resist 6, e.g. epoxy resin, is applied to the exposed surface of the base plate 2 but does not come in contact with the copper pads 4, 5 (NSMD). The copper pads 4, 5 are coated with a further metal 7 for protection against aggressive media, said metal being resistant to the medium surrounding the circuit board, in particular to an ATF.

Triple points, whereat the metallic coating, the copper and the solder resist make contact, are thus prevented by this design. The copper is hermetically shielded from the ATF by means of the metallization. In so doing, the copper cannot be attacked which is a requirement for use of the (otherwise unprotected) circuit board as a control device within a transmission.

FIG. 2 shows a further embodiment of the invention. In this case, identical elements as in FIG. 1 are provided with the same reference numerals as in FIG. 1.

In the second embodiment, the copper pads 4, 5 are partially covered by the solder resist 6 which was applied (SMD). Conducting tracks 8 are furthermore present on the surface of the base plate 2 and are intended to be covered by the solder resist. This means that the metallic coating 7 is applied prior to the solder resist 6 being applied. Otherwise the aforementioned triple points would form. In this embodiment, the external conducting tracks 8, which are actually directly coated with the solder resist 6 and are therefore sufficiently protected, are thus coated with a metal which is then clad with the solder resist.

For that reason, the second embodiment also ensures that all of the exposed copper is hermetically sealed off from the ATF.

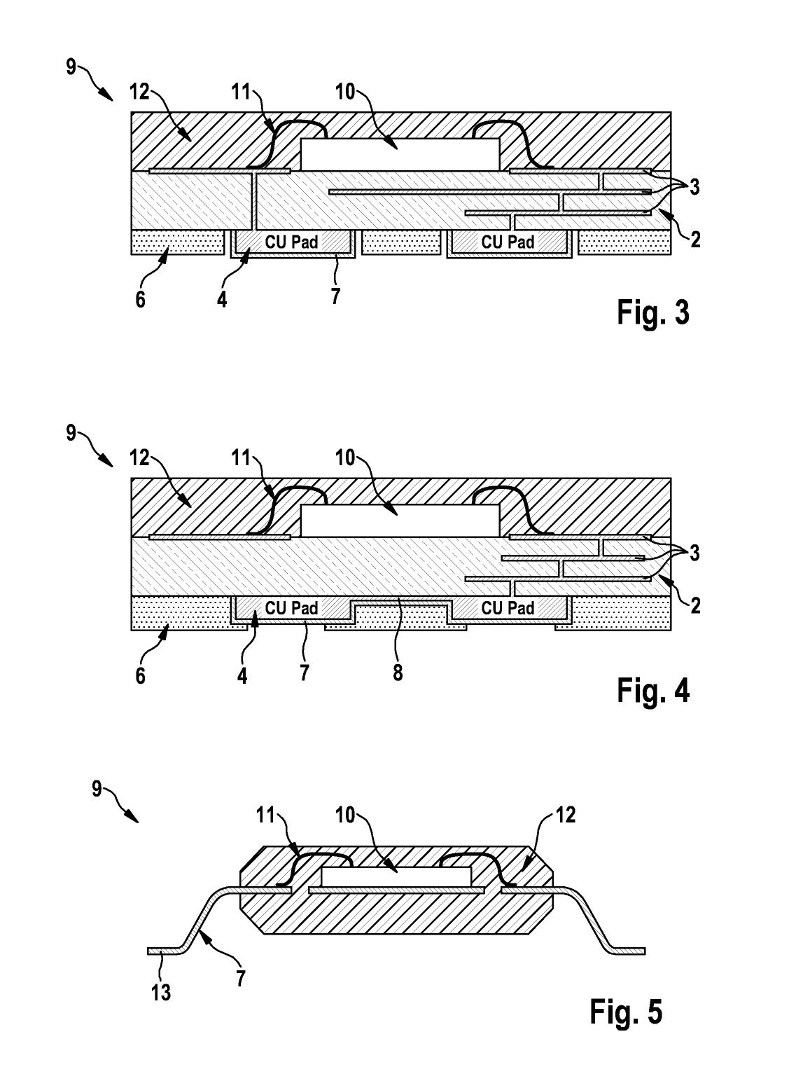

FIG. 3 shows an inventive component 9 in a first embodiment. The design of the base plate 2 and the copper pads 4 for producing an electrical contact is for the most part identical to the design of the circuit board 1 from FIG. 1. For that reason, identical or similar elements are denoted with the same reference numerals. In contrast to the circuit board 1, a semiconductor chip 10 is located on one side of the base plate 2. Said chip can contain various logic circuits, the inputs and outputs of which are actuated via the copper pads 4 of the base plate 2. To this end, the chip 10 is, for example, coupled to the base plate by means of a bonding procedure. In order to protect these bonded connections 11 as well as the chip 10 from outside influences, a plastic casing 12 is applied to the surface of the base plate, which casing completely covers the chip 10 and the bonded connections 11.

The design of solder resist 6, copper pads 4 and coating 7 is identical to the design from FIG. 1.

FIG. 4 shows a component in a further embodiment of the invention. A chip 10 is mounted on a base plate 2 in a manner analogous to FIG. 3, said chip being connected to the base plate 2 in an electrically conductive manner. A plastic casing 12 protects the chip and the bonded connections.

Analogous to FIG. 2, solder resist 6, copper pads 4 and coating 7 are embodied in the layout variant NSMD and are therefore identical to the second embodiment of the circuit board.

FIG. 5 shows a component which is used without a base plate. It comprises contacting elements 13 which are connected to the chip 10, for example, by means of adhesive bonding 11. The plastic casing encompasses thereby not only the chip 10 and the bonded connections 11 but also partially the contacting elements 13. In order to also hermetically seal off all of the copper pads from the ATF in this embodiment, the contacting element has to be completely coated. Said contacting element can alternatively be produced from a material which is resistant to ATF.

1-12. (canceled)

13. An electrical circuit board (1) having at least one layer and having internal and/or external conducting tracks or electrical circuits (3, 8), which circuit board has copper pads (4, 5) arranged on a surface for population with electrical components, and which is at least partially surrounded by liquid media, or is directly exposed thereto, wherein said copper pads (4, 5) and exposed conducting tracks (8) are coated with a further metal (7).

14. The circuit board (1) according to claim 13, characterized in that the coating (7) consists of a metal from the group NiAu, NiPdAu, NiPdAgAu, PdAg, Sn or Ag and all of the surfaces to be coated are completely covered.

15. The circuit board (1) according to claim 13, characterized in that a solder resist (6) is applied to the surface, wherein the solder resist (6) at least partially covers the coated copper pads (4, 5).

16. The circuit board (1) according to claim 13, characterized in that a solder resist (6) is applied to the surface, wherein the solder resist (6) does not come in contact with the coated copper pads (4, 5).

17. The circuit board (1) according to claim 13, characterized in that the circuit board has copper pads (5) for electrically connecting at least two layers of the circuit board.

18. An electrical circuit board (1) having at least one layer and having internal and/or external conducting tracks or electrical circuits (3, 8), which circuit board has copper pads (5) for electrically connecting at least two layers of the circuit board, and which is at least partially surrounded by liquid media, or is directly exposed thereto, wherein said copper pads (4, 5) and exposed conducting tracks (8) are coated with a further metal (7).

19. The circuit board (1) according to claim 18, characterized in that the coating (7) consists of a metal from the group NiAu, NiPdAu, NiPdAgAu, PdAg, Sn or Ag and all of the surfaces to be coated are completely covered.

20. The circuit board (1) according to claim 18, characterized in that a solder resist (6) is applied to the surface, wherein the solder resist (6) at least partially covers the coated copper pads (4, 5).

21. The circuit board (1) according to claim 18, characterized in that a solder resist (6) is applied to the surface, wherein the solder resist (6) does not come in contact with the coated copper pads (4, 5).

22. An electrical component (9), comprising: at least one base plate (2) having internal and/or external conducting tracks or electrical circuits (3, 8) and at least one semiconductor chip (10), which is connected (11) to the base plate (2) and is provided with a plastic casing (12), and copper pads (4) arranged on the surface of the base plate (2) for electrical connection to other components, wherein the component (9) is at least partially surrounded by liquid media, or is directly exposed thereto, and wherein said copper pads (4) and exposed conducting tracks (8) are coated with a further metal (7).

23. The circuit board (1) according to claim 22, characterized in that the coating (7) consists of a metal from the group NiAu, NiPdAu, NiPdAgAu, PdAg, Sn or Ag and all of the surfaces to be coated are completely covered.

24. The electrical component (9) according to claim 22, characterized in that the resistant material consists of either pure Sn, Al or Ni or alloys containing the aforementioned materials or of electrically conductive plastic (self-conducting or by means of conductive additives).

25. The component (9) according to claim 22, characterized in that a solder resist (6) is applied to the surface, wherein the solder resist (6) at least partially covers the coated copper pads (4, 5).

26. The component (9) according to claim 22, characterized in that a solder resist (6) is applied to the surface, wherein the solder resist (6) does not come in contact with the coated copper pads (4, 5).

27. An electrical component (9) comprising: at least one contacting element (13) for electrically connecting the component (9) to other components and a semiconductor chip (10) which is connected (11) to the contacting element (13) and is provided with a plastic casing (12), wherein the component (9) is at least partially surrounded by liquid media, or is directly exposed thereto, and wherein the at least one contacting element (13) is coated with a further metal (7) or consists of a material that is resistant to liquid media which react with copper.

28. The component (9) according to claim 27, characterized in that the coating (7) consists of a metal from the group NiAu, NiPdAu, NiPdAgAu, PdAg, Sn or Ag and all of the surfaces to be coated are completely covered.

29. A method for producing a circuit board (1) according to claim 16, having exclusively internal conducting tracks, comprising the following steps:
production of an at least one-layer base plate (2) having said conducting tracks or electrical circuits (3), said copper pads (4, 5) and possibly a semiconductor chip surrounded by a plastic casing,
application of a solder resist (6) to the surfaces of the base plate (2), and
application of a metallic coating (6) to the copper pads (4, 5).

30. The method according to claim 29, characterized in that at least one of the following steps is additionally taken in order to apply the plastic casing:
application of a structure to the base plate (2) or to the contacting element; and
use of an adhesion promoter prior to applying the plastic coating.

31. A method for producing a circuit board (1) according to claim 15, comprising the following steps:
production of an at least one-layer base plate (2) having said conducting tracks or electrical circuits (3, 8), said copper pads (4, 5) and a semiconductor chip surrounded by a plastic casing,
application of a metallic coating to the copper pads (4, 5) and the external conducting tracks (8),
application of a solder resist (6) to the surfaces of the base plate (2), and
a check of the surface and if need be a refreshing of the coating (7).

32. The method according to claim 31, characterized in that at least one of the following steps is additionally taken in order to apply the plastic casing:
application of a structure to the base plate (2) or to the contacting element; and
use of an adhesion promoter prior to applying the plastic coating.

33. A method for producing a circuit board (1) according to claim 16, comprising the following steps:
production of an at least one-layer base plate (2) having said conducting tracks or electrical circuits (3, 8), said copper pads (4, 5) and a semiconductor chip surrounded by a plastic casing,
application of a metallic coating to the copper pads (4, 5) and the external conducting tracks (8),
application of a solder resist (6) to the surfaces of the base plate (2), and
a check of the surface and if need be a refreshing of the coating (7).

34. The method according to claim 33, characterized in that at least one of the following steps is additionally taken in order to apply the plastic casing:
application of a structure to the base plate (2) or to the contacting element; and
use of an adhesion promoter prior to applying the plastic coating.

35. A method for producing a component (9) according to claim 27, comprising the following steps:
production of a contacting element (13),
application of a coating (7) to the contacting element (13), provided said contacting element contains copper,
production of a semiconductor chip (10) that is surrounded by a plastic casing (12) and is connected (11) to the contacting element (13), wherein the contacting element (13) is partially surrounded by the plastic housing (12), and
a check of the surfaces of the contacting element (13) and if need be a refreshing of the coating (7).

36. The method according to claim 35, characterized in that at least one of the following steps is additionally taken in order to apply the plastic casing:
application of a structure to the base plate (2) or to the contacting element; and
use of an adhesion promoter prior to applying the plastic coating.

37. A method for producing a component (9) according to claim 28, comprising the following steps:
production of a contacting element (13),
application of a coating (7) to the contacting element (13), provided said contacting element contains copper,
production of a semiconductor chip (10) that is surrounded by a plastic casing (12) and is connected (11) to the contacting element (13), wherein the contacting element (13) is partially surrounded by the plastic housing (12), and
a check of the surfaces of the contacting element (13) and if need be a refreshing of the coating (7).

38. The method according to claim 37, characterized in that at least one of the following steps is additionally taken in order to apply the plastic casing:
application of a structure to the base plate (2) or to the contacting element; and
use of an adhesion promoter prior to applying the plastic coating.

39. A transmission, comprising:
at least one circuit board (1) according to claim 1, which are embodied as a control device for said transmission; and
at least one liquid medium that reacts with copper and is present at least in a part of the transmission;
wherein the circuit board (1) is directly exposed to said liquid medium.
